(19) United States
(12) Patent Application Publication
(10) Pub. No.: US 2025/0192501 A1
(43) Pub. Date: Jun. 12, 2025

(54) CABLE MANUFACTURING PROCESS

(71) Applicant: BIOSENSE WEBSTER (ISRAEL) LTD., Yokneam (IL)

(72) Inventors: Assaf Govari, Haifa (IL); Ilya Sitnitsky, Nahariya (IL); Alexander Shechtman, Haifa (IL); Sergey Sobol, Haifa (IL); Faina Oriya Luria, Yoqneam Moshava (IL); Amit Fuchs, Haifa (IL)

(21) Appl. No.: 18/947,040

(22) Filed: Nov. 14, 2024

Related U.S. Application Data
(60) Provisional application No. 63/608,869, filed on Dec. 12, 2023.
(60) Provisional application No. 63/608,872, filed on Dec. 12, 2023.

(51) Int. Cl. H01R 43/02; H01B 13/00; H05K 3/32

(52) U.S. Cl. CPC H01R 43/0256; H01B 13/0003; H01R 43/0263; H05K 3/32

(57) ABSTRACT

An apparatus for manufacturing cable assemblies includes one or more wire sources, multiple grippers, a circuit-board handler and a joining tool. The wire sources are configured to supply a continuous set of wires. The grippers are configured to grip the wires and successively draw predefined lengths of the wires from the wire sources. The circuit-board handler is configured to place a respective circuit board against each predefined length of the wires held by the grippers. The joining tool is configured to connect each circuit board to an end of the corresponding predefined length of wires.

### CROSS-REFERENCE TO RELATED APPLICATION

This application claims the benefit of U.S. Provisional Patent Applications 63/608,869 and 63/608,872, both filed Dec. 12, 2023, whose disclosures are incorporated herein by reference.

### TECHNICAL FIELD

The present disclosure relates generally to electronic wiring, and particularly to methods and systems for manufacturing cable assemblies.

### BACKGROUND

Certain catheters, such as those involved with cardiac mapping and ablating cardiac tissue, typically have 80-100 electrodes, connected to cables by the process above. This large number of connections in small spaces provides the catheter with precision and accuracy. Each electrode (i.e., pad) is connected to a dedicated wire, from the wires of a cable. Accordingly, the cable connecting process adds expense to an already expensive process for manufacturing the catheter.

Connecting cables to printed circuit boards (PCBs) is a manual process, as wires of a fully formed cable must be separated at their ends, stripped to bare metal, and finally, electrically connected to an electrode on a printed circuit board (PCB). The electrical connection is made by processes such as welding, soldering and the like. As the wires are very thin, their stripping to bare metal and electrical connection to the electrodes is a delicate, precise and tedious process. The process requires skilled personnel, making it costly.

### BRIEF DESCRIPTION OF THE DRAWINGS

The present disclosure will be more fully understood from the following detailed description of examples thereof, taken together with the drawings, where like numerals or characters indicate corresponding or like components. Dimensions of components and features shown in the figures are chosen for convenience and clarity of presentation and are not necessarily shown to scale. In the drawings:

FIG. 1 is a schematic top view of a robotic system for manufacturing cable assemblies, in accordance with an example of the present disclosure;

FIG. 2 is a flow chart that schematically illustrates a method for manufacturing cable assemblies using the system of FIG. 1, in accordance with an example of the present disclosure;

FIG. 3 is a diagram showing a cable manufacturing process in accordance with an example of the present disclosure;

FIG. 4A-1 shows a portion of the process of FIG. 3, in accordance with an example of the disclosed subject matter;

FIG. 4A-2 is a cross-sectional view of a first gripper taken along line 2-2 of FIG. 4A-1;

FIGS. 4B-4H show portions of the process of FIG. 3.

FIG. 5 shows a process for forming a cable assembly into a cable component, in accordance with an example of the disclosed subject matter;

FIG. 6A is a diagram of a cable component in accordance with an example of the disclosed subject matter; and

FIG. 6B is a section of the cable of the cable component of FIG. 6A including a cross-sectional view of the cable taken along line 4-4 of FIG. 6A.

### DETAILED DESCRIPTION OF EXAMPLES

### Overview

Diagnostic catheters, such high-density mapping and ablation catheters, used, for example, in cardiac mapping and cardiac tissue ablating, typically include between 30-120 electrodes. Each electrode is connected at a distal end to a dedicated wire. Each wire extends through a catheter shaft and connects to a printed circuit board (PCB) at its proximal end.

The cables used in the high-density mapping and ablation catheters have very thin wires, typically 10 wires of approximately 0.05 mm in diameter, resulting in cables of approximately 0.5 mm in diameter, to accommodate limited space in the catheter. Multiple cables are housed in the shaft of the catheter, e.g. 10 cables. Due to the small dimensions of the wires and cables, attaching wires to PCBs, and doing the same for the same wires at the opposite end of the cable, is a delicate, tedious and time-consuming process. Such processing must be done manually, and requires skilled labor, which adds expense to manufacturing costs.

The present disclosure provides an automated (machine-based) method and system for building cable assemblies from wires concurrently with connecting the ends of the wires to a substrate, e.g., a printed circuit board (PCB). The terms “cable assembly” and “cable” are used interchangeably herein. The connecting is, for example, by welding, but may also be by soldering, such that the cable is built during a welding process, where individual wires are welded, or otherwise electrically connected or joined to corresponding electrodes or wire pads (also referred to herein as pads) or the like on a PCB.

The process originates by obtaining multiple wires, each wire from its own spool. The individual wires are each supported at a free end by a first gripper, such as a first robotic arm, which takes up each wire, unwinding it from its respective spool. The first gripper pulls the gripped wires a distance beyond the respective spools. A second gripper, such as a second robotic arm, grips the wires at a position between the first gripper and the spools. The first gripper and the second gripper cooperatively maintain the wires in tension.

For each wire, the end of each wire is moved into alignment with a pad, at a known position on a first substrate, which is, for example, a PCB. The first substrate (i.e., PCB) is mounted on an XYZ stage, which supports and moves the PCB for fine tuning and positioning of each wire with respect to a designated pad of the substrate. The exposed end of each wire is joined to the designated pad, for example, by welding with a joining tool, to maintain electrical connections. The joining of each wire to the respective pad is, for example, concurrent welding and/or soldering. In an alternate example, the joining may be by welding and/or soldering in succession.

The opposite end of each wire of the aforementioned multiple wires is gripped by the second gripper, that cooperates with the first gripper, to maintain the wires in tension to keep the wires taught. The multiple wires are also maintained at a sufficient spacing apart from each other, for example, at distances corresponding to the distances between centers of adjacent pads on the substrates, i.e., PCBs.

The second ends of the multiple wires are processed similar to the first ends of the wires. The second ends of the wires are joined (connected), i.e., electrically connected, for example by welding, each wire in succession to the respective pad, of a second PCB, in accordance with that disclosed for the first ends of the wires.

At least by this time, a third gripper, such as a third robotic arm, is introduced to the process. The third gripper grips the wires between the spools and the second PCB (and the second gripper). The wires, now connected to the first and second PCBs, and which extend outward from the PCBs, may now be cut from the respective first and second PCBs.

Excess wires extending outward from the substrate pads on each of the substrates are cut off and removed, resulting in an intermediate structure prior to the wires being twisted or otherwise formed into a cable between the PCBs. For example, the wires extend between the substrates for a length of approximately 1.5 meters. The resultant structure is a cable assembly, formed of the wires attached to oppositely disposed PCBs. The third gripper maintains a grip on the wires on their respective spools, allowing the process of manufacturing the cable assembly to be repeated.

The resultant cable assembly, with its wires under tension (e.g., all under the same tension) and connected to PCBs at the opposite ends of the wires, can now be formed into a cable component, formed of the now-formed cable attached to and between the PCBs. The cable is formed as the wires of the intermediate are, for example, rotated together (i.e., twisted at one or both ends) to form a cable. Optionally, the device used to hold each PCB, one or both, may be rotated, to form the cable.

The now formed cable may now be shielded, to prevent electromagnetic interference with other wires, cables and the like. For example, a conductive barrier may be placed around the cable. The conductive barrier may be, for example, metal wires, metal sheets, metal foams, metal screens and coating of metal inks.

The shielded cable may now be jacketed, to provide the cable with electrical insulation and mechanical integrity. The jacketing may be, for example, an electrically insulating material, which is coated onto, or otherwise covers, the now-shielded cable. The coating for the jacket may be, for example, a perylene coating.

### System Description

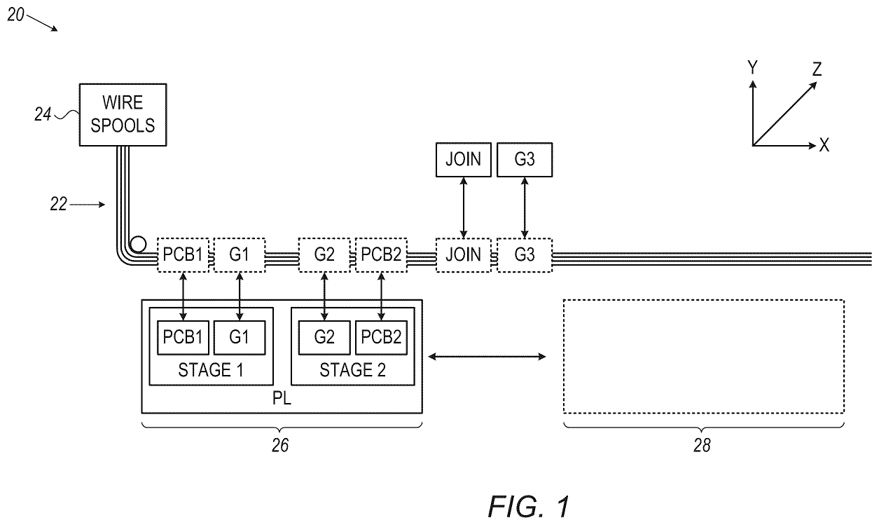

FIG. 1 is a schematic top view of a robotic system 20 for manufacturing cable assemblies, in accordance with an example of the present disclosure. The coordinate system used in the description is shown at the top-right of the figure. In addition, the description refers to “right” and “left” (or “right-hand side” and “left-hand side”). All these axes and directions are used in a non-limiting manner for ease of explanation.

System 20 automatically manufactures cable assemblies from a plurality of wires 22 that are originally wound on respective spools 24 (or, more generally, from wires drawn from one or more continuous wore sources). Each cable assembly manufactured by system 20 comprises a predefined length of wires 22, connected at one end to a first circuit board and at the other end to a second circuit board. In alternative examples, the disclosed technique can be used for manufacturing cable assemblies having only one circuit board at one end, with the opposite end having open-ended wires.

In the present example the circuit boards comprise Printed Circuit Boards (PCBs) denoted PCB1 and PCB2, and the cable length is 1.5 meters. Alternatively, other configurations can be used. The ends of wires 22 may be connected to pads of PCB1 and PCB1 using any suitable connection process, e.g., soldering and/or welding.

System 20 comprises a platform (denoted “PL” in the figure and in the explanation below) that is movable along the X axis, e.g., along a rail, between a left-hand side position 26 and a right-hand side position 28.

Two stages, denoted “STAGE1” and “STAGE2”, are mounted on platform PL. STAGE1 comprises a first gripper denoted G1, and a first PCB handler denoted PCB1. Similarly, STAGE2 comprises a second gripper denoted G2, and a second PCB handler denoted PCB2. In addition, system 20 comprises a third gripper (denoted G3) and a joining tool (denoted JOIN), both located between left-hand side position 26 and right-hand side position 28 of PL.

It is noted that the use of the term “joining” and “JOIN” is done by way of example. Generally, any other suitable joining or connection tool and process can be used, e.g., soldering, welding or any other.

Each of the above-described system components (each of the grippers, each of the PCB handlers, and the joining tool) has two respective positions—an extended position (depicted using a dashed line) and a collapsed position (depicted using a solid line). In the extended position, the system component is aligned with the set of wires 22 along the Y axis. In the collapsed position, the system component is moved away from wires 22.

Grippers G1 and G2, and PCB handlers PCB1 and PCB2, are movable along the X axis by moving platform PL. Gripper G3 and joining tool JOIN are stationary along the X axis. Each of the system components can also be moved in the Z direction, e.g., in order to access the wires and/or to avoid collision with another system component.

Each of the grippers (G1, G2, G3) is configured to grip the set of wires 22 when in the extended position. When a pair of grippers (e.g., G1 and G3, or any other pair) grip wires 22, the grippers apply a predefined amount of tension to the length of wires held between them. At certain times wires 22 may be gripped by a single gripper. In such cases, the single gripper applies the predefined amount of tension to the length of wires between the gripper and spools 24.

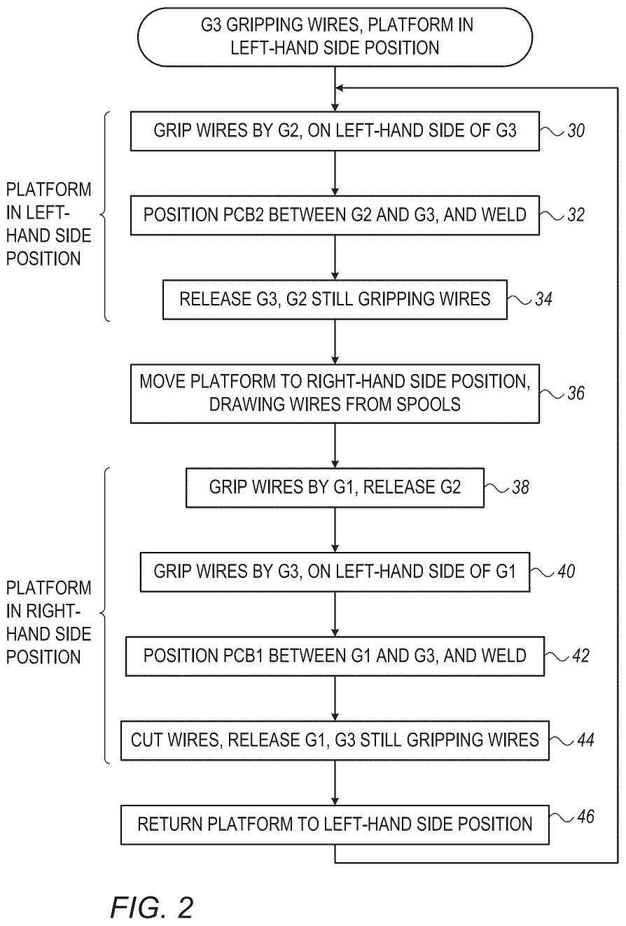

FIG. 2 is a flow chart that schematically illustrates a method for manufacturing cable assemblies using system 20 of FIG. 1, in accordance with an example of the present disclosure. In the initial system configuration, wires 22 are gripped only by G3, and platform PL is positioned in left-hand side position 26. Wires 22 are held by G3 with a suitable tension. The wires are spaced apart from one another by suitable spacing that matches the respective pads of PCB1 and PCB2 to which the wires will be connected.

At a G2 gripping operation 30, G2 grips the wires on the left-hand side of G3. At a PCB2 placement & joining operation 32, PCB2 handler extends to the extended position to place PCB2 against wires 22. Joining tool JOIN then connects each wire to a respective pad on PCB2. The connecting operation (e.g., welding or soldering) may be performed simultaneously on all wires, or sequentially. At a G3 releasing operation 34, G3 releases the wires. The wires are still held by G2.

At a platform moving operation 36, platform PL moves from left-hand position 26 to right-hand position 28. The platform moves while wires 22 are held by gripper G2. As a result, an additional length of wires 22 is drawn from spools 24, for use in the currently manufactured cable assembly. This length (which corresponds to the displacement between positions 26 and 28 of PL) will be the length of the cable assembly.

At a G1 gripping operation 38, gripper G1 grips the wires. Then, G2 releases the wires. At a G3 gripping operation 40, G3 grips the wires, on the left-hand side of G1. At a PCB1 placement & joining operation 42, PCB1 handler extends to the extended position to place PCB1 against wires 22. Joining tool JOIN then connects each wire to a respective pad on PCB1. As before, JOIN may connect the wires to the pads concurrently, or one wire at a time.

At a cutting operation 44, a cutting tool (not seen in the figure) cuts the wires to the right of G3 (between G3 and PCB1). G1 is now released. The ends of wires 22 are held by G3 alone.

At this stage, the cable assembly (a length of wires 22, connected at one end to PCB1 and at the other end to PCB2) is complete. The cable assembly is taken off the system for further processing (e.g. twisting, shielding and/or jacketing). Examples of these operations are disclosed, for example, in the related application “Manufacturing of Shielded Multi-Wire Cable Assemblies,” Attorney Docket Number BIO6866USPSP1, cited above.

At a platform returning operation 46, platform PL moves back from right-hand side position 28 to left-hand side position 26. The system configuration is now identical to the initial position, and the system is ready to manufacture the next cable assembly. The method thus loops back to operation 30 above.

### Alternative Implementations

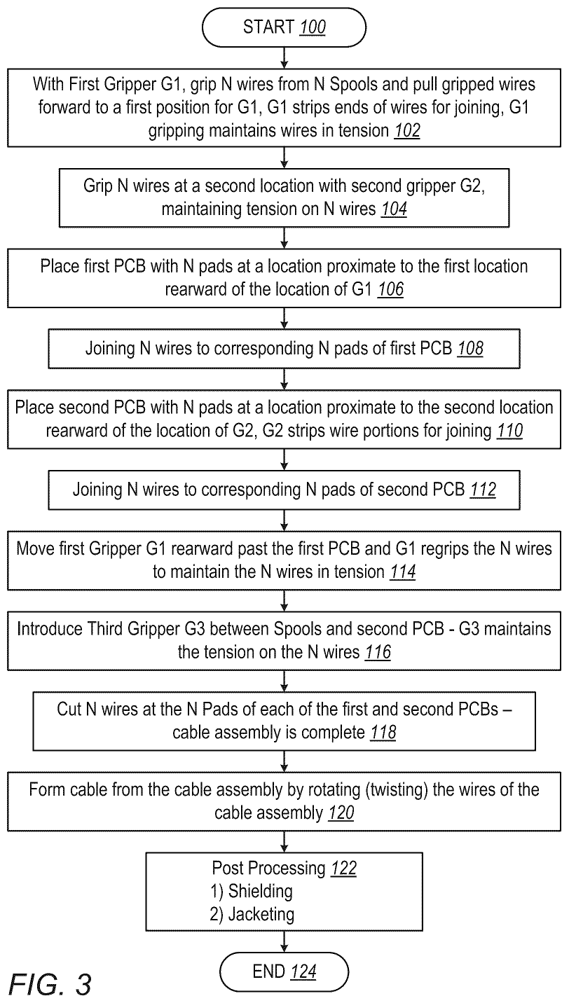

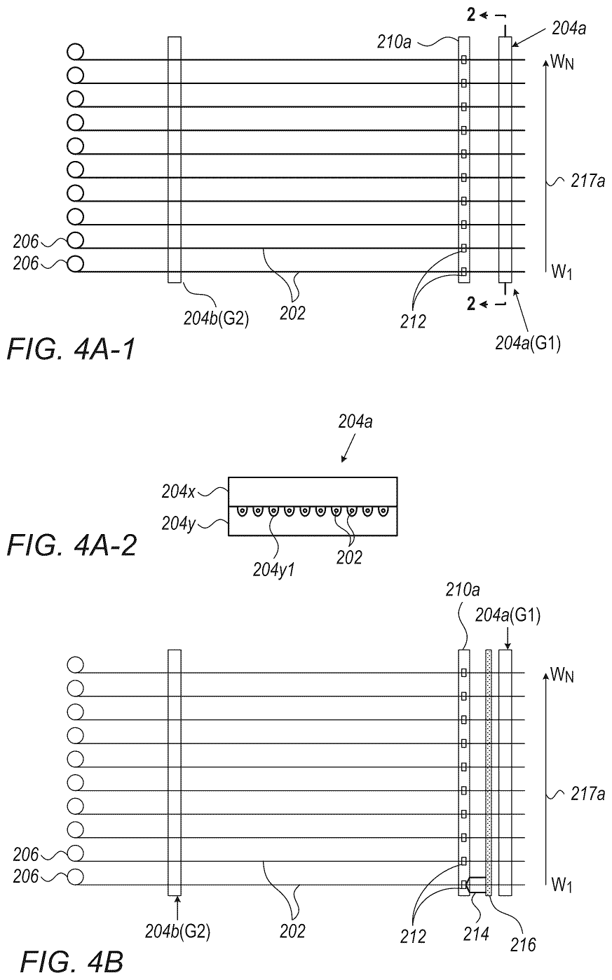

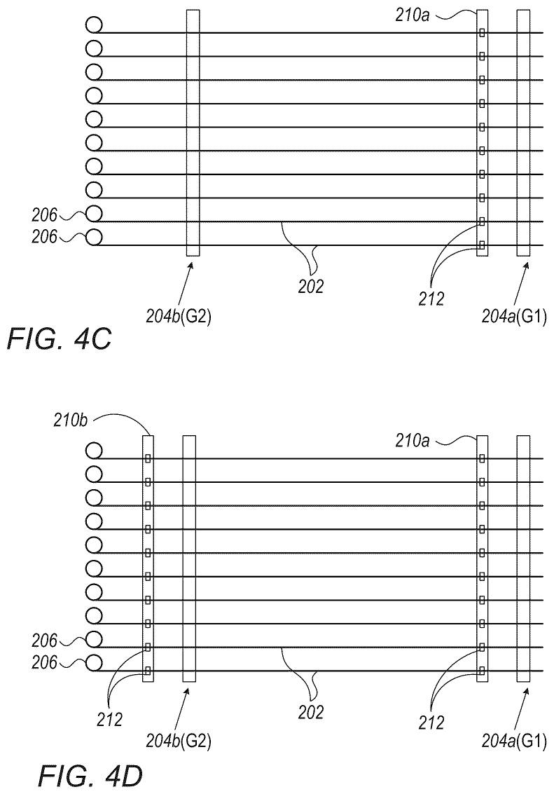

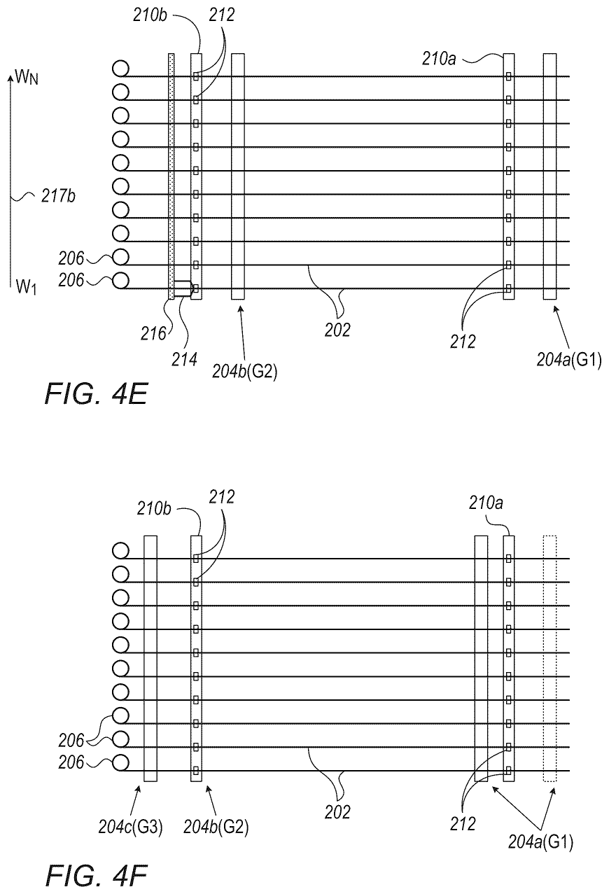

FIG. 3 shows an example manufacturing process for a cable assembly 220, and ultimately a cable component 400 of a cable 400x formed from wires 202, electrically connected at opposite ends to a substrate 210a, 210b, for example, printed circuit boards (PCBs), shown for example, in FIG. 4G. The process comprises multiple subprocesses, detailed in blocks 100-124. While the process is defined in an order, this order is an example order, and the subprocesses may be performed in different orders. From this process forming a cable assembly 220, further processing of the cable assembly 220 results in a cable component 400, a cable 400x electrically connected to PCBs 210a, 210b at opposite ends, which, for example, is suitable for use in high density mapping and ablation catheters.

The manufacturing process begins at a START block 100. The wires 202 are all on their respective spools, with for example, N wires 202, where N represents a plural integer number of members of a finite set. As shown in FIG. 4A-1 to 4H, and throughout the drawing figures, N is, for example, the integer 10, representing 10 wires 202 and the wires are approximately 0.05 mm in diameter, and are for example, Copper wires.

The process moves to block 102. Here, a first robotic gripper G1 204a, which is configured to be controlled in one or more directions, pulls each of N wires 202, from a corresponding individual spool 206 (unwinding the wires 202 from its individual spool 206).

The robotic gripper G1 204a pulls the N wires 202 from the respective spool 206 to a first position, maintaining the N wires 202 in tension, e.g., a pre-defined range of tension, as shown in FIG. 4A-1. A second gripper G2 204b, for example, a robotic arm, may now be introduced, between the spools 206 and the first gripper G1 104a. Th grippers G1 204a, G2 204b cooperate to hold the N wires 202 in tension. The gripper G1 204a then proceeds to strip all of the N wires 202, for example, at the same time, at their ends to bare (exposed) metal.

The gripper G1 204a holds all of the N wires 202 between portions 204x and 204y (portion 204y including grooves 204y1 to accommodate the N wires 202, which seat in the grooves 204y1 with a defined amount of pressure on the wires 202, to prevent the wires 202 from being damaged), as shown in FIG. 4A-2. In the first G1 204a and second G2 204b grippers, the N wires 202 are laterally spaced from each other at a spacing corresponding to the distance between centers of adjacent pads 212, such as at approximately 0.2 mm, to avoid any contacts.

The second robotic gripper G2 204b, similar to the first robotic gripper G1, and in accordance with the robotic Gripper G1 described above, grips all N wires 202 at a location rearward or upstream of the first position of the first griper G1 204a. This arrangement allows for the N wires 202 to be maintained in tension, at block 104, as shown in FIG. 4B. For example, the tension may be at a force of approximately 6 gm.

With the grippers G1 204a and G2 204b gripping the wires 202 in tension, and maintaining the wires 202 in tension, the process moves to block 106. At this subprocess, a first substrate, for example, a first printed circuit board (PCB) 210a, with N pads 212, corresponding to the N wires 202, is mounted on an XYZ stage (not shown). The XYZ stage supports and moves the PCB 210a for fine tuning and positioning of the wire 202 with respect to a designated pad 212 of the first PCB 210a. The supported PCB 210a is moved into position with respect to the wires 202. The PCB 210a position is adjusted by moving the XYZ stage, such the wires 202 align with the pads 212 of the PCB 210a, as shown in FIG. 4B. The pads 212 are, for example, formed of an electrically conductive metal or other material, suitable to support electrical connections when a wire 202 is joined thereto, for example, by welding. Also, as shown in FIG. 4B, the first PCB 210a is slightly rearward (upstream) of the first gripper G1 204a.

Moving to block 108, each of the wires 202 is joined with a joining tool to a corresponding pad 212 of the first PCB 210a, at FIG. 4B, to electrically connect or electrically couple the wire 202 to its corresponding pad 212 of the first PCB 210a. The joining, for example, includes welding, but may also be performed by soldering fastening techniques that maintain electrical or other conductivity between the wire 202 and the pad 212. Optionally, the joining tool is operated in an automated procedure, e.g., without human intervention. The welding is performed sequentially by a moving a welding head 214 along a guide 216, such as a rail or linear stage. The welding head 214 welds each wire 202 to its corresponding pad 212, in succession, e.g., one after another, in the direction of the arrow 217a from W₁ to W_{N}. The resultant structure is shown in FIG. 4C. Optionally, the joining tool may be guided to each of the pads in succession based on vision guided control using one or more cameras.

The process then moves to block 110, where the second gripper G2 204b strips the wires 202, exposing bare metal for a uniform length. A second printed circuit board (PCB) 210b, with N pads 212, corresponding to the N wires 202, on an XYZ stage, is moved under the stripped portions of the wires 202. The XYZ stage (not shown) moves the pads 212 on the second PCB 210b into alignment with each of the N wires 202, as shown in FIG. 4D. The second PCB 210b is slightly rearward (upstream) of the second gripper G2 204b.

Moving to block 112, each of the wires 202, at its stripped portion, is joined to a corresponding pad 212 of the PCB 210b, as shown in FIG. 4E. This joining is, for example, by welding, as s detailed above, to create electrical connections between the wires 202 and the corresponding pads 212, as detailed for the first PCB 210a, above. Like the previous welding for the first PCB 210a, the welding is performed sequentially by a moving a welding head 214 along the guide 216. The welding head 214, welds the respective wire 202 to the corresponding pad 212 sequentially, for example, in the direction of the arrow 217b from W₁ to the last wire in the sequence W_{N}. The resulting structure is shown in FIG. 4F. For example, each of the N the wires 202 extends a length of approximately 1.5 meters between the oppositely disposed PCBs 201a, 210b.

With all N wires 202 joined at both ends to respective PCBs 210a, 210b, the process moves to block 114, where the first gripper G1 204a is moved rearward (upstream), from a position forward or downstream of the first PCB 210a (shown in broken lines) to a position slightly beyond (inward or upstream) of the first PCB 210a. Once at this new rearward position, the first gripper G1 204a regrips the N wires 202, holding and maintaining the N wires 202, in cooperation with the second gripper G2 204b, in tension, for example, of a tension force of approximately 6 gm, to maintain the wires 202 in a taught state, at block 114. This is shown in FIG. 4F.

The process moves to block 116, where a third gripper (G3) 204c, for example, a robotic arm, grips the wires 202 between the spools 206 and the second PCB 210b. This gripping of the wires 202 maintains the wires 202 being held in tension. Optionally, this subprocess of block 116 may be performed before or simultaneous with the subprocess of block 114. The process moves to block 118, where the wires 202 extending outward from the ends of the PCBs 210a, 210b are cut (shown by scissors 218), either manually or automatically, at or proximate to the connections, e.g., welds on the pads 212, as shown in FIG. 4G. The cut-off wires are discarded. The resulting structure is a cable assembly 220, shown in FIG. 4H. For example, the N wires 202 extend between the respective PCBs 210a, 210b approximately 1.5 meters in length.

The third gripper (G3) 204c maintains tension on the wires from the spools 206, and may now pull the wires 202 from the spools to start another process as described herein, shown beginning in FIG. 4A-1 and described above.

Returning to FIG. 4H, the grippers G1 204a, G2 204b maintain the tension on all N wires 202 of the cable assembly 220. The cable assembly may now undergo additional processing, beginning at block 120. intermediate 220 is now complete and suitable for for example, being wound into a additional processing, cable component 400, with the cable 400x between the PCBs 210a, 210b, with opposite ends of the cable 400x (i.e., the wires 202, attached thereto.

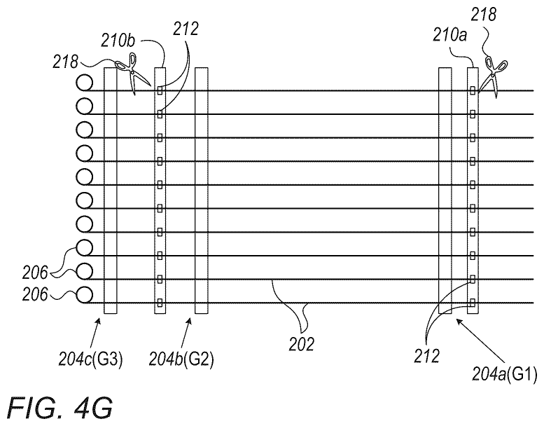

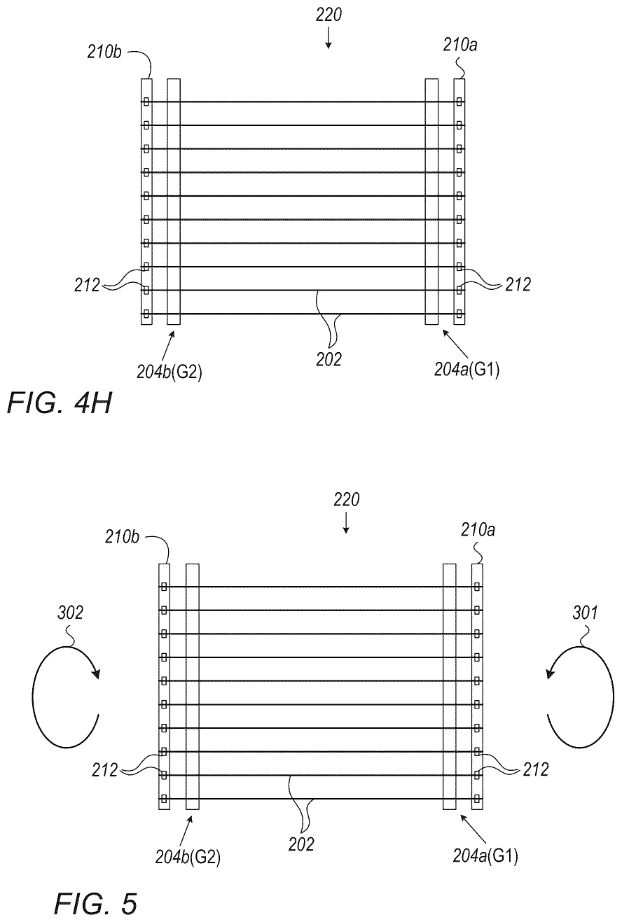

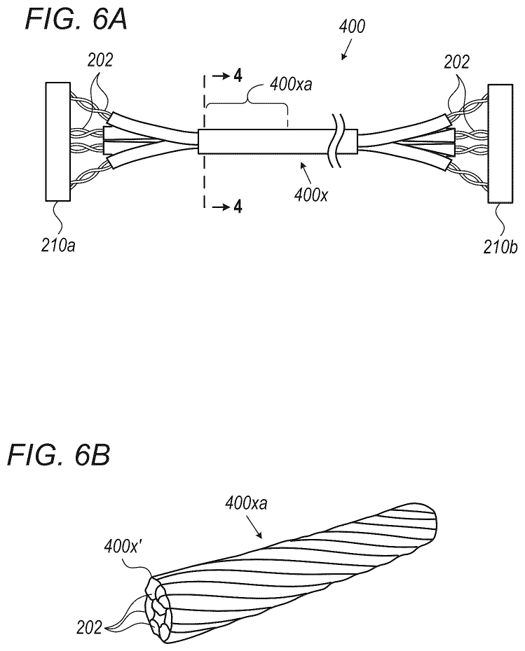

The process moves to block 120, as shown in FIG. 5, where the cable assembly 220, with its wires 202 held in tension by at least two grippers G1 204a, G2 204b, is rotated (twisted), by twisting one or both (in opposite directions) grippers G1 204a, G2 204b, in accordance with the rotations, represented by the arrows 300, 301. Rotating (twisting) continues until a cable component 400 is formed, as shown in FIGS. 6A and 6B.

The process moves to post processing of the cable component at block 122. The post processing includes, for example, shielding and jacketing of the cable 400x (FIGS. 6A and 6B).

The shielding of the cable 400x prevents electromagnetic interference with other wires, cables and the like. For example, a conductive barrier may be placed around the cable. The conductive barrier may be, for example, metal wires, metal sheets, metal foams, metal screens and coating of metal inks.

The shielded cable is, for example, subsequently jacketed. The jacketing provides the cable with electrical insulation and mechanical integrity. The jacketing may be, for example, an electrically insulating material, which is coated or otherwise covered, for example, perylene coating. Alternatively, other materials may be used for coating the cable 400x, for example, by painting, spray coating or the like.

For example, a segment 400xa (with the shield removed) of the cable 400x is shown in FIG. 6B, with the end 400x′ of the segment 400xa shown in cross section (taken along line 4-4 of FIG. 6A) to show the intertwining of the wires 202.

The process moves to block 124 where it ends. The process may be repeated as desired, for as many production cycles as desired.

### EXAMPLES

### Example 1

An apparatus for manufacturing cable assemblies includes one or more wire sources, multiple grippers, a circuit-board handler and a joining tool. The wire sources are configured to supply a continuous set of wires. The grippers are configured to grip the wires and successively draw predefined lengths of the wires from the wire sources. The circuit-board handler is configured to place a respective circuit board against each predefined length of the wires held by the grippers. The joining tool is configured to connect each circuit board to an end of the corresponding predefined length of wires.

### Example 2

The apparatus according to example 1, further including a cutting tool, configured to successively cut each predefined length of wires from the wire sources, thereby producing a plurality of cable assemblies, each cable assembly including a respective circuit board connected to a respective predefined length of the set of wires.

### Example 3

The apparatus according to example 1, wherein the grippers are configured to maintain a continuous grip on the set of wires throughout production of the plurality of cable assemblies.

### Example 4

The apparatus according to example 1, wherein the grippers are configured to maintain the gripped set of wires at a predefined tension.

### Example 5

The apparatus according to example 1, further including an additional circuit-board handler, configured to place an additional circuit board against an opposite end of each predefined length of the wires held by the grippers; wherein the joining tool is further configured to connect the additional circuit board to the opposite end, thereby producing each cable assembly with both the circuit board and the additional circuit board.

### Example 6

The apparatus according to example 1, wherein the gripped wires extend along an axis, and wherein at least one of the grippers is configured to draw predefined lengths of the wires by moving along the axis.

### Example 7

The apparatus according to example 6, further including a platform that is movable along the axis, wherein the at least one of the grippers is mounted on the platform.

### Example 8

The apparatus according to example 6, wherein at least another of the grippers is stationary with respect to the axis.

### Example 9

The apparatus according to example 6, wherein the grippers and the joining tool are movable perpendicularly to the axis, for approaching and moving away from the gripped wires.

### Example 10

A method for manufacturing cable assemblies includes supplying a continuous set of wires by one or more wire sources. Using multiple grippers, the wires are gripped, and predefined lengths of the wires are successively drawn from the wire sources. Using a circuit-board handler, a respective circuit board is placed against each predefined length of the wires held by the grippers. Using a joining tool, each circuit board is connected to an end of the corresponding predefined length of wires.

As used herein, the terms “about” or “approximately” for any numerical values or ranges indicate a suitable dimensional tolerance that allows the part or collection of components to function for its intended purpose as described herein.

Various features of the disclosure which are, for clarity, described in the contexts of separate examples may also be provided in combination in a single example. Conversely, various features of the disclosure which are, for brevity, described in the context of a single example may also be provided separately or in any suitable sub-combination.

The examples described of the present disclosure are not limited by what has been particularly shown and described hereinabove. Rather the scope of the disclosure includes both combinations and sub-combinations of the various features described hereinabove, as well as variations and modifications thereof which would occur to persons skilled in the art upon reading the foregoing description and which are not disclosed in the prior art.

1. An apparatus for manufacturing cable assemblies, the apparatus comprising:
one or more wire sources, configured to supply a continuous set of wires;
multiple grippers, configured to grip the wires and successively draw predefined lengths of the wires from the wire sources;
a circuit-board handler, configured to place a respective circuit board against each predefined length of the wires held by the grippers; and
a joining tool, configured to connect each circuit board to an end of the corresponding predefined length of wires.

2. The apparatus according to claim 1, further comprising a cutting tool, configured to successively cut each predefined length of wires from the wire sources, thereby producing a plurality of cable assemblies, each cable assembly comprising a respective circuit board connected to a respective predefined length of the set of wires.

3. The apparatus according to claim 1, wherein the grippers are configured to maintain a continuous grip on the set of wires throughout production of the plurality of cable assemblies.

4. The apparatus according to claim 1, wherein the grippers are configured to maintain the gripped set of wires at a predefined tension.

5. The apparatus according to claim 1,
further comprising an additional circuit-board handler, configured to place an additional circuit board against an opposite end of each predefined length of the wires held by the grippers;
wherein the joining tool is further configured to connect the additional circuit board to the opposite end, thereby producing each cable assembly with both the circuit board and the additional circuit board.

6. The apparatus according to claim 1, wherein the gripped wires extend along an axis, and wherein at least one of the grippers is configured to draw predefined lengths of the wires by moving along the axis.

7. The apparatus according to claim 6, further comprising a platform that is movable along the axis, wherein the at least one of the grippers is mounted on the platform.

8. The apparatus according to claim 6, wherein at least another of the grippers is stationary with respect to the axis.

9. The apparatus according to claim 6, wherein the grippers and the joining tool are movable perpendicularly to the axis, for approaching and moving away from the gripped wires.

10. A method for manufacturing cable assemblies, the method comprising:
supplying a continuous set of wires by one or more wire sources;
using multiple grippers, gripping the wires and successively drawing predefined lengths of the wires from the wire sources;
using a circuit-board handler, placing a respective circuit board against each predefined length of the wires held by the grippers; and
using a joining tool, connecting each circuit board to an end of the corresponding predefined length of wires.

11. The method according to claim 10, further comprising, using a cutting tool, successively cutting each predefined length of wires from the wire sources, thereby producing a plurality of cable assemblies, each assembly comprising a respective circuit board connected to a respective predefined length of the set of wires.

12. The method according to claim 10, wherein gripping the wires comprises maintaining a continuous grip on the set of wires throughout production of the plurality of cable assemblies.

13. The method according to claim 10, wherein gripping the wires comprises maintaining the gripped set of wires at a predefined tension.

14. The method according to claim 10, further comprising:
using an additional circuit-board handler, placing an additional circuit board against an opposite end of each predefined length of the wires held by the grippers; and
using the joining tool, connecting the additional circuit board to the opposite end, thereby producing each cable assembly with both the circuit board and the additional circuit board.

15. The method according to claim 10, wherein the gripped wires extend along an axis, and wherein gripping the wires comprises drawing predefined lengths of the wires by moving along the axis.

16. The method according to claim 15, wherein moving along the axis comprises moving a platform on which one of the grippers is mounted.

17. The method according to claim 15, wherein at least another of the grippers is stationary with respect to the axis.

18. The method according to claim 15, further comprising moving the grippers and the joining tool perpendicularly to the axis, for approaching and moving away from the gripped wires.
